(19) United States
(12) Patent Application Publication
(10) Pub. No.: US 2025/0364449 A1
(43) Pub. Date: Nov. 27, 2025

(54) AMPLIFYING CIRCUIT

(71) Applicant: SUMITOMO ELECTRIC DEVICE INNOVATIONS, INC., Yokohama-shi (JP)

(72) Inventor: Ikuo NAKASHIMA, Yokohama-shi (JP)

(73) Assignee: SUMITOMO ELECTRIC DEVICE INNOVATIONS, INC., Yokohama-shi (JP)

(21) Appl. No.: 19/208,932

(22) Filed: May 15, 2025

(30) Foreign Application Priority Data
May 22, 2024 (JP) 2024-083459

(51) Int. Cl. H01L 23/66; H03F 1/56; H03F 3/195

(52) U.S. Cl. CPC H01L 23/66; H03F 1/565; H03F 3/195; H01L 2223/6611; H01L 2223/6655; H03F 2200/451

(57) ABSTRACT

An amplifying circuit includes an amplifier that amplifies a high frequency signal and outputs the high frequency signal that is amplified to an output terminal, a first resistor having a first end and a second end, the first end being connected to a wiring between the amplifier and the output terminal, a second resistor having a first end and a second end, the first end being connected to the second end of the first resistor, a first capacitor having a first electrode and a second electrode, the first electrode being connected to a node between the second end of the first resistor and the first end of the second resistor, the second electrode being connected to a reference potential, and a second capacitor having a first electrode and a second electrode, the first electrode being connected to the second end of the second resistor.

### CROSS REFERENCE TO RELATED APPLICATIONS

This application claims priority based on Japanese Patent Application No. 2024-083459 filed on May 22, 2024, and the entire contents of the Japanese patent application are incorporated herein by reference.

### TECHNICAL FIELD

The present disclosure relates to an amplifying circuit.

### BACKGROUND

Patent literature (WO 2004/032188) discloses a packaged RF power device. The RF power device includes at least one transistor, an RF signal input lead, an RF signal output lead, an output matching circuit, and a video bypassing circuit. The RF signal input lead and the RF signal output lead are coupled to the transistor. The output matching circuit is coupled to the RF signal output lead. The transistor is coupled to the RF signal output lead line through the output matching circuit. The video bypass circuit is coupled to the RF signal output lead through the output matching circuit.

### SUMMARY

An amplifying circuit according to an embodiment of the present disclosure includes an amplifier, a first resistor, a second resistor, a first capacitor, and a second capacitor. The amplifier is configured to amplify a high frequency signal and output the high frequency signal that is amplified to an output terminal, the first resistor has a first end and a second end, the first end being connected to a wiring between the amplifier and the output terminal, the second resistor has a first end and a second end, the first end being connected to the second end of the first resistor, the first capacitor has a first electrode and a second electrode, the first electrode being connected to a node between the second end of the first resistor and the first end of the second resistor, the second electrode being connected to a reference potential, and the second capacitor has a first electrode and a second electrode, the first electrode being connected to the second end of the second resistor, the second electrode being connected to the reference potential.

### BRIEF DESCRIPTION OF THE DRAWINGS

FIG. 1 is a diagram schematically showing a configuration of an amplifying circuit according to an embodiment.

FIG. 2 is a circuit diagram of a semiconductor device in an embodiment.

FIG. 3 is a plan view of a semiconductor device.

FIG. 4 is a side view of a semiconductor device.

FIG. 5 is a cross-sectional view of a semiconductor device taken along line V-V shown in FIG. 3.

FIG. 6 is a cross-sectional view of a semiconductor device taken along line VI-VI shown in FIG. 3

FIG. 7 is a cross-sectional view of a semiconductor device taken along line VII-VII shown in FIG. 3

FIG. 8 is a perspective view of a baseband termination circuit.

FIG. 9 is a cross-sectional view of a baseband termination circuit taken along line IX-IX of FIG. 8.

FIG. 10A is a diagram showing a manufacturing process of a baseband termination circuit.

FIG. 10B is a diagram showing a manufacturing process of a baseband termination circuit.

FIG. 11A is a diagram showing a manufacturing process of a baseband termination circuit.

FIG. 11B is a diagram showing a manufacturing process of a baseband termination circuit.

FIG. 12A is a diagram showing a manufacturing process of a baseband termination circuit.

FIG. 12B is a diagram showing a manufacturing process of a baseband termination circuit.

FIG. 13 is a perspective view of a baseband termination circuit according to a comparative example.

FIG. 14A is a circuit diagram of a baseband termination circuit.

FIG. 14B is a circuit diagram of a baseband termination circuit.

FIG. 15 is a diagram showing a circuit used in a simulation to confirm the effect of electrical characteristics of a baseband termination circuit.

FIG. 16 is a graph showing simulation results.

FIG. 17A is a diagram showing a manufacturing process of a baseband termination circuit, which is a modification.

FIG. 17B is a diagram showing a manufacturing process of a baseband termination circuit, which is a modification.

FIG. 18A is a diagram showing a manufacturing process of a baseband termination circuit, which is a modification.

FIG. 18B is a diagram showing a manufacturing process of a baseband termination circuit, which is a modification.

FIG. 19A is a diagram showing a manufacturing process of a baseband termination circuit, which is a modification.

FIG. 19B is a diagram showing a manufacturing process of a baseband termination circuit, which is a modification.

### DETAILED DESCRIPTION

A high-frequency amplifying circuit is used in, for example, a base station of a cellular phone. In the high-frequency amplifying circuit, not only a signal frequency but also a baseband frequency is amplified as noise with an increase in the bandwidth of a communication frequency. In order to suppress such noise, a circuit that reduces a low frequency band including the baseband frequency may be provided in the amplifying circuit. In one example, the low frequency band reduction circuit includes a capacitor and a resistor to absorb a noise component in the low frequency band. At this time, the resistor generates heat, and the temperature at or near the resistor rises. Since an excessive temperature rise at or near the resistor affects the operation and life of the resistor, it is desired to improve heat dissipation for the heat generated in the resistor.

An object of the present disclosure is to provide an amplifying circuit that can improve heat dissipation for the heat generated in a resistor.

### Description of Embodiments of Present Disclosure

First, the contents of embodiments of the present disclosure will be listed and explained.

[1] An amplifying circuit according to an embodiment of the present disclosure includes an amplifier, a first resistor, a second resistor, a first capacitor, and a second capacitor. The amplifier is configured to amplify a high frequency signal and output the amplified high frequency signal to an output terminal, the first resistor has a first end and a second end, the first end being connected to a wiring between the amplifier and the output terminal, the second resistor has a first end and a second end, the first end being connected to the second end of the first resistor, the first capacitor has a first electrode and a second electrode, the first electrode being connected to a node between the second end of the first resistor and the first end of the second resistor, the second electrode being connected to a reference potential, and the second capacitor has a first electrode and a second electrode, the first electrode being connected to the second end of the second resistor, the second electrode being connected to a reference potential.

In the amplifying circuit according to the above [1], at least two resistors, such as the first resistor and the second resistor, are provided. In this case, it is possible to disperse heat generation points compared to the case where there is only one resistor. Thus, heat dissipation for the heat generated in the resistor can be improved. Further, the first resistor is provided, and thus it is possible to increase the attenuation rate of the frequency band passing through the first capacitor.

[2] In the amplifying circuit according to the above [1], a resistance value of the first resistor may be smaller than a resistance value of the second resistor. In this case, an amount of the heat generated in the first resistor and an amount of the heat generated in the second resistor, which has a smaller current than the first resistor, can be brought closer to uniformity.

[3] The amplifying circuit according to the above [1] or [2] may further include a base material having a main surface on which the first resistor, the second resistor, the first capacitor, and the second capacitor are provided. On the main surface, the first capacitor, the second capacitor, or both the first capacitor and the second capacitor may be disposed between the first resistor and the second resistor. In this case, since the first resistor and the second resistor can be sufficiently spaced apart from each other, the heat generation points can be effectively dispersed, and heat dissipation can be further improved.

[4] In the amplifying circuit according to the above [3], the main surface may have a rectangular planar shape elongated in a first direction. The first resistor and the second resistor may have a rectangular planar shape elongated in a second direction intersecting the first direction. In this case, it is possible to improve heat dissipation while avoiding the base material from becoming long in the first direction and maintaining a sufficient distance between the first resistor and the second resistor.

[5] The amplifying circuit according to the above [3] or [4] may include a wire bonding pad provided on the main surface and connected to the first end of the first resistor, and a bonding wire connecting the wire bonding pad to the wiring. The first resistor may be disposed between the wire bonding pad and the first capacitor. In this case, the wire bonding pad and the first resistor can be efficiently disposed on the main surface.

[6] The amplifying circuit according to the above [1] or [2] may further include a base material having a main surface on which the first resistor, the second resistor, the first capacitor, and the second capacitor are provided. The first resistor and the second resistor may be film resistors formed on the main surface. Thus, the first resistor and the second resistor are in close contact with the base material, and thus, heat dissipation can be improved as compared to the case where a surface-mounted chip resistor is used.

[7] The amplifying circuit according to the above [3] or [4] may further include a base material having a main surface on which the first resistor, the second resistor, the first capacitor, and the second capacitor are provided. The first resistor and the second resistor may be diffused resistors formed in the base material. Thus, the first resistor and the second resistor are included in the base material, and thus, heat dissipation can be improved as compared to the case where a surface-mounted chip resistor is used.

### Details of Embodiments of Present Disclosure

Specific examples of an amplifying circuit of the present disclosure will be described below with reference to the drawings. It is noted that, the present disclosure is not limited to the examples, but is defined by the scope of the claims, and is intended to include all modifications within the meaning and scope equivalent to the scope of the claims. In the following description, the same elements are denoted by the same reference numerals in the description of the drawings, and redundant description will be omitted.

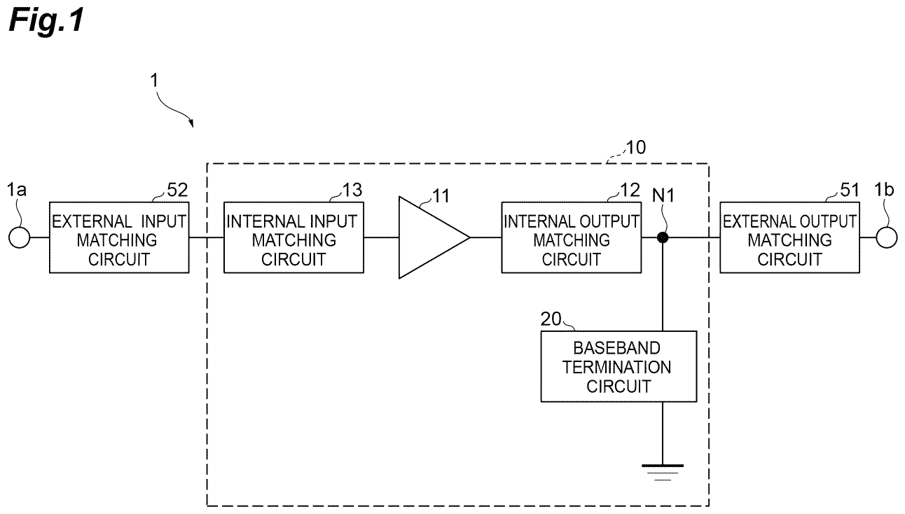

The amplifying circuit of the present embodiment is a high-output high-frequency amplifying circuit used in a base station of mobile communication. FIG. 1 is a diagram schematically showing a configuration of an amplifying circuit 1 according to the present embodiment. As shown in FIG. 1, amplifying circuit 1 includes an input terminal la, an output terminal 1b, a semiconductor device 10, an external output matching circuit 51, and an external input matching circuit 52. Semiconductor device 10 includes an amplifier 11, an internal output matching circuit 12, an internal input matching circuit 13, and a baseband termination circuit 20 (also referred to as a video bypass circuit or an envelope frequency termination circuit). Input terminal la is connected to amplifier 11 via external input matching circuit 52 and internal input matching circuit 13. External input matching circuit 52 and internal input matching circuit 13 match the load connected to input terminal la and the input impedance of amplifier 11.

Amplifier 11 is connected to output terminal 1b via internal output matching circuit 12 and external output matching circuit 51. Internal output matching circuit 12 and external output matching circuit 51 match the load connected to output terminal 1b and the output impedance of amplifier 11. The high frequency signal input to input terminal la is transmitted to amplifier 11 via external input matching circuit 52 and internal input matching circuit 13. Amplifier 11 amplifies the high frequency signal and outputs the amplified signal to output terminal 1b via internal output matching circuit 12 and external output matching circuit 51.

Baseband termination circuit 20 is connected between a node N1, which is located between internal output matching circuit 12 and external output matching circuit 51, and a reference potential such as the ground. Baseband termination circuit 20 is a circuit for improving VBW (i.e., video bandwidth). The video bandwidth is used as an indicator of a distortion bandwidth. When VBW is small, measurement of 3rd order Inter-Modulation Distortion (IMD3) of a two-tone signal corresponding to the bandwidth (for example, 400 MHz) of the amplifier results in a difference in signal strength between the IMD3 component on the low frequency side and the IMD3 component on the high frequency side. When asymmetry occurs in the IMD3 in this way, distortion compensation using digital-predistortion (DPD) cannot provide sufficient distortion characteristics because the amount of distortion improvement is reduced. A cause of the asymmetry of the IMD3 is known to be a second-order intermodulation distortion (IMD2) component generated in the difference frequency component of the two-tone signal. The difference frequency component is a signal component in a low frequency band included in the range of the baseband frequency. By providing baseband termination circuit 20, the impedance of the low frequency band at node N1 is reduced. Thus, this increases the video bandwidth and suppresses the IMD2 component. This improves the asymmetry of the IMD3 and allows the DPD to provide sufficient distortion compensation.

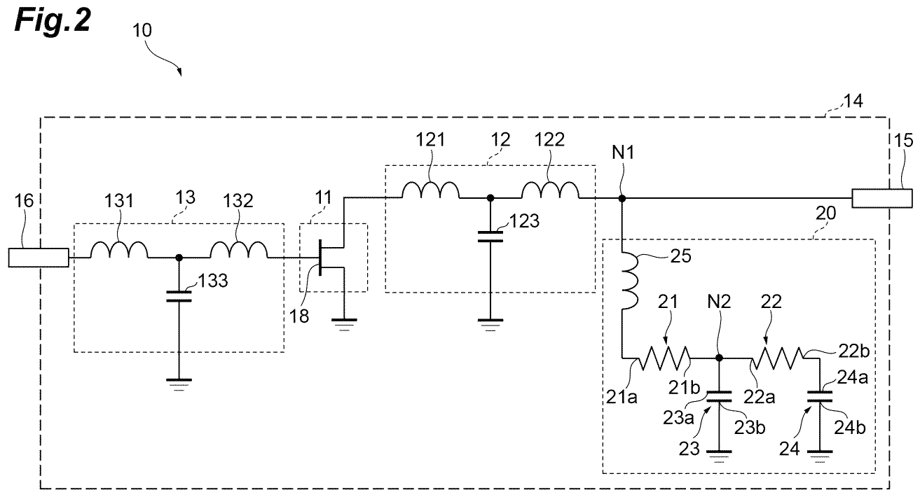

FIG. 2 is a circuit diagram of semiconductor device 10 in the present embodiment. As shown in FIG. 2, semiconductor device 10 includes a package 14, output leads 15, and input leads 16. Amplifier 11, internal output matching circuit 12, internal input matching circuit 13, and baseband termination circuit 20 are mounted in package 14. Output lead 15 and input lead 16 connect the circuit in package 14 to the outside.

Amplifier 11 includes a transistor 18. Transistor 18 is, for example, a field effect transistor (FET) such as a gallium-nitride high electron mobility transistor (GaN HEMT) or a laterally diffused metal oxide semiconductor (LDMOS). A control terminal (gate) of transistor 18 is electrically connected to input lead 16 via internal input matching circuit 13. A first current terminal (for example, drain) of transistor 18 is electrically connected to output lead 15 via internal output matching circuit 12. A second current terminal (for example, source) of transistor 18 is connected to a wiring having a reference potential, such as a ground potential.

Internal output matching circuit 12 includes a wire 121 and a wire 122 that function as inductors. Wire 121 and wire 122 are connected in series to each other, a first end of the series circuit is connected to the first current terminal of transistor 18, and a second end of the series circuit is connected to output lead 15. Further, internal output matching circuit 12 includes a capacitor 123. A first electrode of capacitor 123 is connected to a node between wire 121 and wire 122, and a second electrode of capacitor 123 is connected to a reference potential such as the ground. Thus, internal output matching circuit 12 forms a so-called T-type filter. The number of wires and the number of capacitors in internal output matching circuit 12 can be set as appropriate.

Internal input matching circuit 13 includes a wire 131 and a wire 132 that function as inductors. Wire 131 and wire 132 are connected in series to each other, a first end of the series circuit is connected to input lead 16, and a second end of the series circuit is connected to the control terminal of transistor 18. Further, internal input matching circuit 13 includes a capacitor 133. A first electrode of capacitor 133 is connected to a node between wire 131 and wire 132, and a second electrode of capacitor 133 is connected to a reference potential such as the ground. Thus, internal input matching circuit 13 forms a so-called T-type filter. The number of wires and the number of capacitors in internal input matching circuit 13 can be set as appropriate.

Baseband termination circuit 20 includes a first resistor 21, a second resistor 22, a first capacitor 23, a second capacitor 24, and a wire 25 that functions as an inductor. First resistor 21 includes a first end 21a and a second end 21b. First end 21a is connected to node N1 of a wiring between amplifier 11 and output terminal 1b (or output lead 15) via wire 25. Second resistor 22 has a first end 22a and a second end 22b. First end 22a is connected to second end 21b of first resistor 21. First capacitor 23 includes a first electrode 23a and a second electrode 23b. First electrode 23a is connected to a node N2 between second end 21b of first resistor 21 and first end 22a of second resistor 22. Second electrode 23b is connected to a reference potential such as the ground. Second capacitor 24 includes a first electrode 24a and a second electrode 24b. First electrode 24a is connected to second end 22b of second resistor 22. Second electrode 24b is connected to a reference potential such as the ground.

An inductance of wire 25 suppresses the high frequency signal in the operating band amplified by amplifier 11 from passing through first capacitor 23 and second capacitor 24 to the ground. Thus, wire 25 has an inductance such that it has a high impedance in the frequency band of the operating band. The inductance of wire 25 is, for example, 1 nH or more. First capacitor 23 and second capacitor 24 each has a low impedance at a frequency corresponding to the bandwidth of the high frequency signal amplified by amplifier 11. A capacitance value of first capacitor 23 is smaller than a capacitance value of second capacitor 24. The capacitance value of first capacitor 23 is, for example, 51 pF to 470 pF, and is 130 pF in one example. The capacitance value of second capacitor 24 is, for example, 510 pF to 4700 pF, and is 1500 pF in one example. First resistor 21 and second resistor 22 are damping resistors. For example, when a capacitor (for example, a parasitic capacitance) is connected in parallel to first capacitor 23, second capacitor 24, and wire 25, unnecessary resonance may occur. By providing first resistor 21 and second resistor 22, unnecessary resonance can be suppressed. The resistance value of first resistor 21 is smaller than the resistance value of second resistor 22. The resistance value of first resistor 21 may be equal to or less than half the resistance value of second resistor 22. The resistance value of first resistor 21 is, for example, 0.5 Ω to 1 Ω, and is 1 Ω in one example. The resistance value of second resistor 22 is, for example, 1 Ω to 3 Ω, and is 2 Ω in one example.

Since the capacitance value of first capacitor 23 is small, first capacitor 23 contributes to attenuation of a high frequency component. Since the high frequency component attenuated by first capacitor 23 passes through first resistor 21, the attenuation of the high frequency component increases as the resistance value of first resistor 21 increases. On the other hand, since the capacitance value of second capacitor 24 is large, second capacitor 24 contributes to attenuation of a low frequency component. Since the low frequency component attenuated by second capacitor 24 passes through first resistor 21 and second resistor 22, the attenuation of the low frequency component increases as the sum of the resistance values of first resistor 21 and second resistor 22 increases.

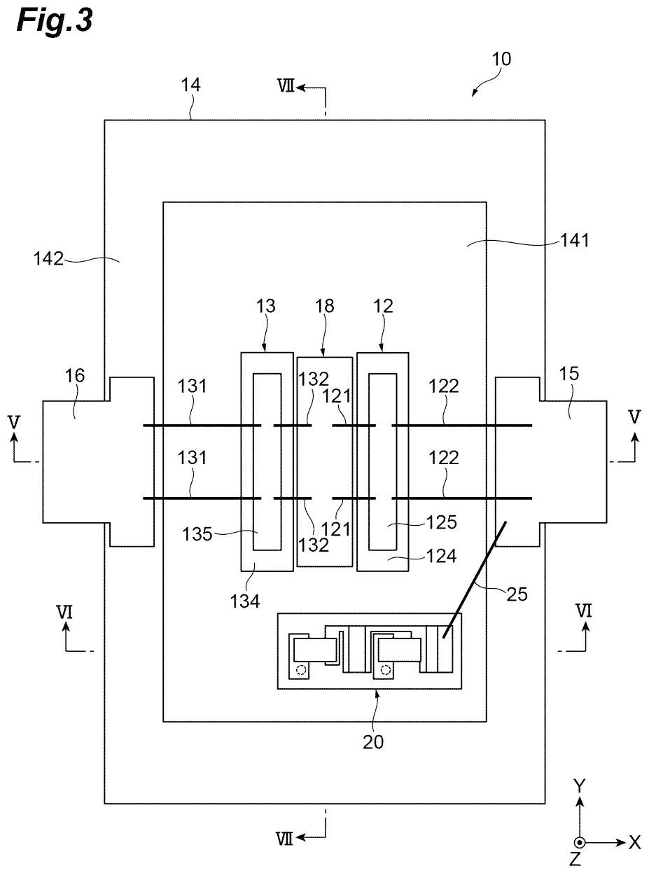

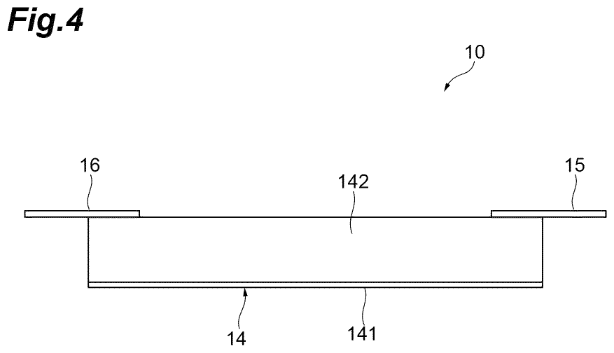

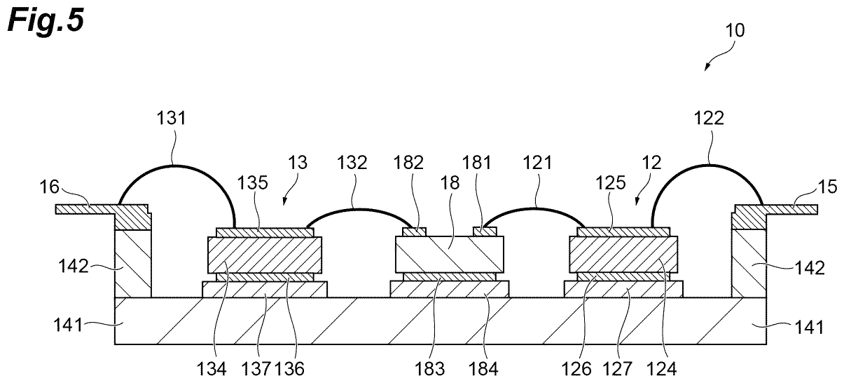

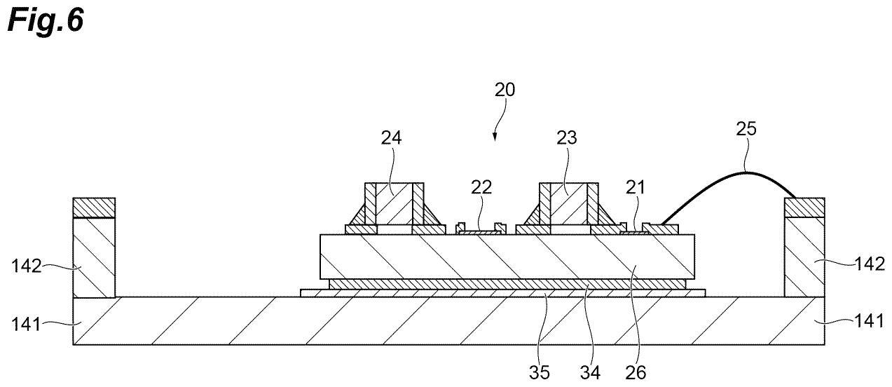

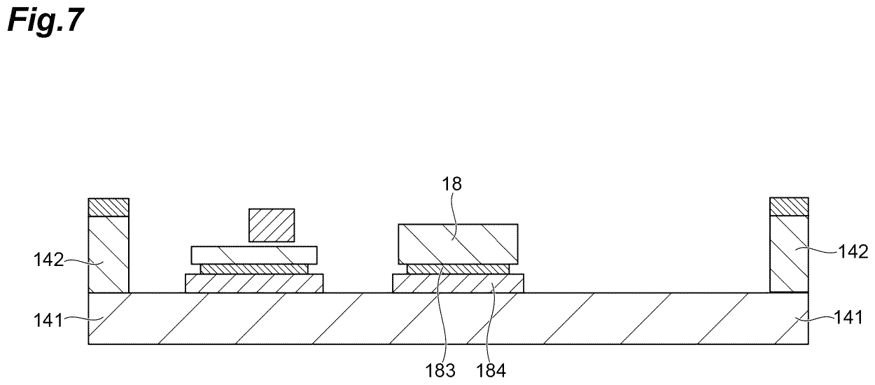

FIG. 3 is a plan view of semiconductor device 10 in the present embodiment. FIG. 4 is a side view of semiconductor device 10. FIG. 5 is a cross-sectional view of semiconductor device 10 taken along line V-V shown in FIG. 3. FIG. 6 is a cross-sectional view of semiconductor device 10 taken along line VI-VI shown in FIG. 3. FIG. 7 is a cross-sectional view of semiconductor device 10 taken along line VII-VII shown in FIG. 3. A normal direction of a top surface of a base substrate 141 is defined as a Z direction, a direction from input lead 16 to output lead 15 is defined as an X direction, and a direction orthogonal to the X direction and the Z direction is defined as a Y direction.

Package 14 includes base substrate 141, a frame body 142, and a lid (not shown). Base substrate 141 is a conductive substrate such as a laminated substrate containing copper and molybdenum. A reference potential such as a ground potential is supplied to base substrate 141. Frame body 142 and the lid mainly include a dielectric material such as a resin, for example, Flame Retardant Type 4 (FR-4) or ceramic. Frame body 142 is bonded to the top surface of base substrate 141 by a bonding material such as a metal paste or a brazing material. Transistor 18, baseband termination circuit 20, internal output matching circuit 12, and internal input matching circuit 13 are disposed in a region surrounded by frame body 142 on base substrate 141. Internal input matching circuit 13, transistor 18, and internal output matching circuit 12 are disposed in this order in the X direction. In other words, transistor 18 is disposed between internal input matching circuit 13 and internal output matching circuit 12 in the X direction. The lid is bonded to a top surface of frame body 142 by an insulating adhesive (not shown) such as a resin. Base substrate 141, frame body 142, and the lid seal transistor 18 in a space.

Output lead 15 and input lead 16 are bonded to the top surface of frame body 142. Output lead 15 is disposed on the top surface of a portion of frame body 142 that is closer to internal output matching circuit 12. Input lead 16 is disposed on the top surface of a portion of frame body 142 closer to internal input matching circuit 13. As shown in FIG. 4, output lead 15 and input lead 16 protrude from frame body 142 toward the side.

Internal output matching circuit 12 includes a dielectric substrate 124, a top electrode 125 provided on the top surface of dielectric substrate 124, and a bottom electrode 126 provided on a bottom surface of dielectric substrate 124. Capacitor 123 shown in FIG. 2 is formed by dielectric substrate 124, and top electrode 125 and bottom electrode 126 interposing dielectric substrate 124. Bottom electrode 126 is conductively bonded to base substrate 141 by a conductive bonding material 127, such as silver paste. Internal input matching circuit 13 includes a dielectric substrate 134, a top electrode 135 provided on a top surface of dielectric substrate 134, and a bottom electrode 136 provided on a bottom surface of dielectric substrate 134. Capacitor 133 shown in FIG. 2 is formed by dielectric substrate 134, and top electrode 135 and bottom electrode 136 interposing dielectric substrate 134. Bottom electrode 136 is conductively bonded to base substrate 141 by a conductive bonding material 137, such as silver paste. Dielectric substrates 124 and 134 are, for example, ceramic substrates. Top electrodes 125 and 135 are, for example, metal films. Top electrode 125 of internal output matching circuit 12 is electrically connected to a first current terminal 181 (for example, drain) of transistor 18 by wire 121 (bonding wire), and is electrically connected to output lead 15 by wire 122 (bonding wire). Top electrode 135 of internal input matching circuit 13 is electrically connected to input lead 16 by wire 131 (bonding wire) and is electrically connected to a control terminal 182 (gate) of transistor 18 by wire 132 (bonding wire). In the illustrated example, wires 121, 122, 131, and 132 are each provided in pairs, but the number of wires 121, 122, 131, and 132 may each be one, or even three or more. A second current terminal 183 (for example, source) of transistor 18 is provided on a bottom surface of transistor 18 and is conductively bonded to base substrate 141 by a conductive bonding material 184, such as silver paste.

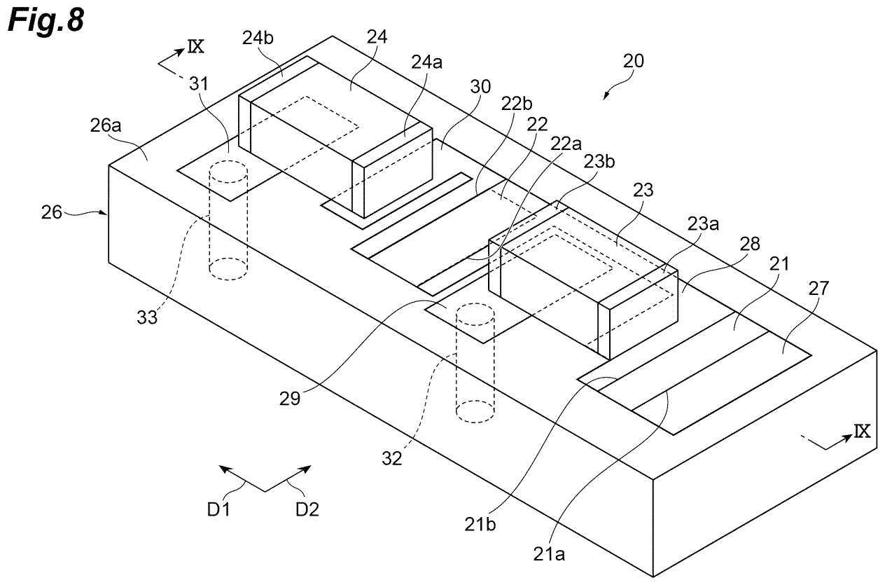

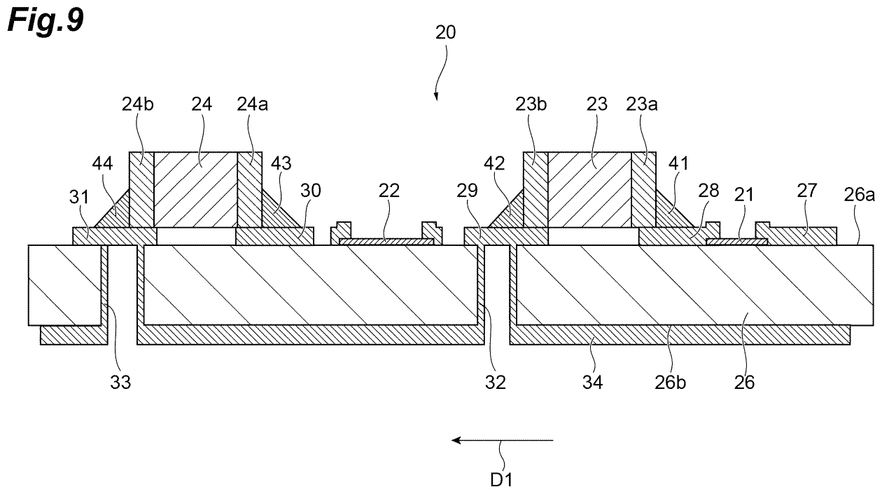

FIG. 8 is a perspective view of baseband termination circuit 20. FIG. 9 is a cross-sectional view of baseband termination circuit 20 taken along line IX-IX of FIG. 8. Baseband termination circuit 20 further includes an insulating base material 26, and forms a baseband termination module. Base material 26 is, for example, a ceramic substrate. The ceramic substrate is, for example, an alumina substrate or an aluminum nitride substrate. Aluminum nitride has a higher thermal conductivity and a better heat dissipation compared to alumina. Alternatively, base material 26 may be a semiconductor substrate such as a silicon (Si) substrate or a silicon carbide (SiC) substrate. SiC has a higher thermal conductivity and a better heat dissipation compared to Si. Base material 26 has a main surface 26a and a rear surface 26b. A metal film 34 is formed on the entire surface of rear surface 26b, and metal film 34 is bonded to base substrate 141 by a conductive bonding material 35 (see FIG. 6) such as silver paste, whereby base material 26 is fixed to base substrate 141. First resistor 21, second resistor 22, first capacitor 23, second capacitor 24, a wire bonding pad 27, and pattern wirings 28, 29, 30, and 31 are provided on main surface 26a of base material 26. Main surface 26a of base material 26 has, for example a rectangular planar shape elongated in a direction D1 (first direction). Direction DI may coincide with the X direction or may intersect the X direction.

In the illustrated example, wire bonding pad 27, first resistor 21, first capacitor 23, second resistor 22, and second capacitor 24 are disposed in this order along direction D1. In other words, first capacitor 23 is disposed between first resistor 21 and second resistor 22. Second capacitor 24 may be disposed between first resistor 21 and second resistor 22, or both first capacitor 23 and second capacitor 24 may be disposed between first resistor 21 and second resistor 22. First resistor 21 is disposed between wire bonding pad 27 and first capacitor 23.

First resistor 21 and second resistor 22 are, for example, thin film resistors formed on main surface 26a of base material 26. First resistor 21 and second resistor 22 are, for example, metallic nitride films such as tantalum nitride (TaN or Ta₂N) or metallic oxide films, or alloy films such as nichrome (NiCr) alloys. The thickness and resistivity of first resistor 21 may be the same as the thickness and resistivity of second resistor 22. Each of first resistor 21 and second resistor 22 has, for example a rectangular planar shape elongated in a direction D2 (second direction) intersecting direction D1. However, the planar shapes of first resistor 21 and second resistor 22 are not limited to this. For example, a length of first resistor 21 in direction D2 is equal to a length of second resistor 22 in direction D2. Further, when a resistance value of first resistor 21 is smaller than a resistance value of second resistor 22, a width of first resistor 21 in direction DI is smaller than a width of second resistor 22 in direction D1. A film thickness of each of first resistor 21 and second resistor 22 is, for example, in a range of 0.05 μm to 0.5 μm. Heat generated in first resistor 21 and second resistor 22 is released to base substrate 141 through base material 26.

Wire bonding pad 27 and pattern wiring 28, 29, 30, and 31 are metal films formed on main surface 26a of base material 26, for example, gold (Au) films. As an underlying layer of gold (Au), nickel (Ni) in contact with main surface 26a and palladium (Pd) interposed between nickel (Ni) and gold (Au) may be further provided. The film thickness of each of wire bonding pad 27 and pattern wirings 28, 29, 30, and 31 is, for example, within a range of 1 μm to 4 μm including the underlying layer. Wire bonding pad 27 is electrically connected to output lead 15 (that is, the wiring between amplifier 11 and output terminal 1b) via wire 25 (see FIG. 3). Further, wire bonding pad 27 is connected to first end 21a of first resistor 21 by being in contact with one side of first resistor 21. Pattern wiring 28 is connected to second end 21b of first resistor 21 by being in contact with the other side of first resistor 21 opposite to the one side. Further, pattern wiring 28 is connected to first end 22a of second resistor 22 by being in contact with one side of second resistor 22. A pattern wiring 30 is connected to second end 22b of second resistor 22 by being in contact with the other side of second resistor 22 opposite to the one side.

A pattern wiring 29 is separated from pattern wiring 28 and electrically connected to metal film 34 of rear surface 26b through a via 32 penetrating base material 26. Thus, pattern wiring 29 is connected to a reference potential such as a ground potential. A pattern wiring 31 is separated from pattern wiring 30 and electrically connected to metal film 34 of rear surface 26b through a via 33 penetrating base material 26. Thus, pattern wiring 31 is connected to a reference potential such as a ground potential. Each of vias 32 and 33 may be formed by embedding a conductor in a through hole or by depositing a conductor film on the wall surface of the through hole. When the conductor film is deposited on the wall surface of the through hole, the region surrounded by the conductor film may be a cavity or may be filled with a resin.

In the illustrated example, first capacitor 23 and second capacitor 24 are multi-layer ceramic capacitors (MLCC) which are surface mount devices (SMD). First capacitor 23 has first electrode 23a and second electrode 23b which are solder-plated. Second capacitor 24 has first electrode 24a and second electrode 24b which are solder-plated. First capacitor 23 is disposed so as to straddle between pattern wiring 28 and pattern wiring 29. First electrode 23a of first capacitor 23 is conductively bonded to pattern wiring 28 by a conductive bonding material 41, and thus is electrically connected to second end 21b of first resistor 21 and first end 22a of second resistor 22. Second electrode 23b of first capacitor 23 is conductively bonded to pattern wiring 29 by a conductive bonding material 42, and thus is connected to a reference potential. Second capacitor 24 is disposed so as to straddle between pattern wiring 30 and pattern wiring 31. First electrode 24a of second capacitor 24 is conductively bonded to pattern wiring 30 by a conductive bonding material 43, and thus is electrically connected to second end 22b of second resistor 22. Second electrode 24b of second capacitor 24 is conductively bonded to pattern wiring 31 by a conductive bonding material 44, and thus is connected to a reference potential. Conductive bonding materials 41, 42, 43, and 44 are, for example, solder, and in on example, SAC 305.

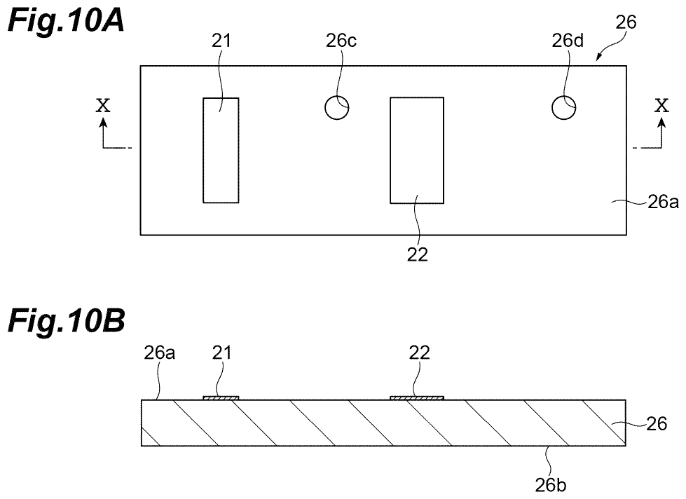

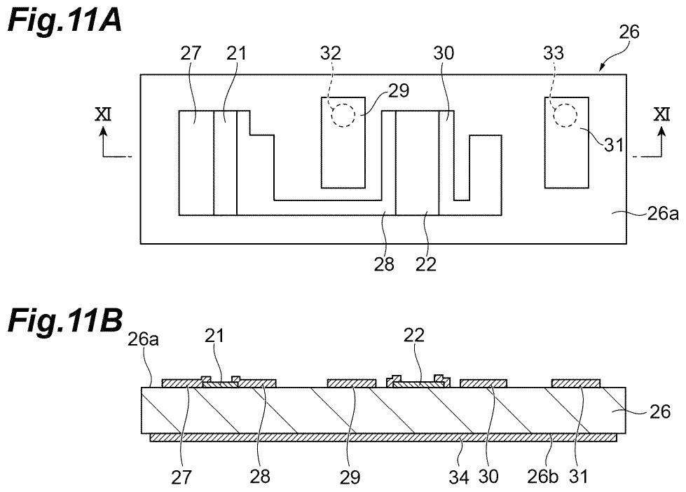

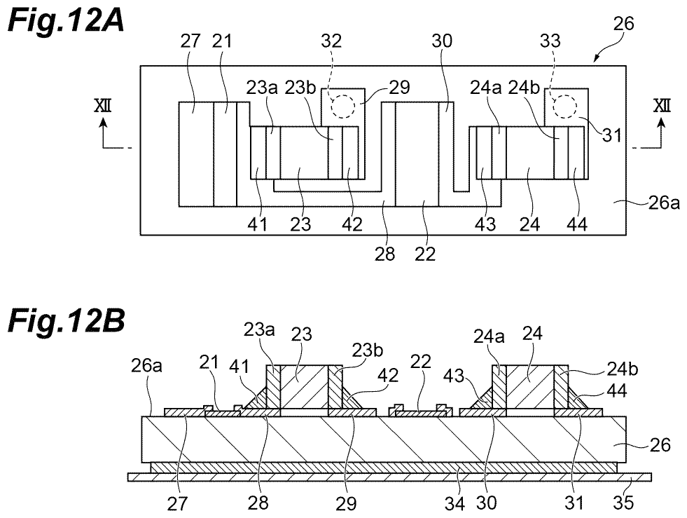

FIG. 10A, FIG. 10B, FIG. 11A, FIG. 11B, FIG. 12A, and FIG. 12B are diagrams each showing a manufacturing process of baseband termination circuit 20. Each of FIG. 10A, FIG. 11A and FIG. 12A shows a plan view, and each of FIG. 10B, FIG. 11B and FIG. 12B shows a cross-sectional view taken along each of X-X line, XI-XI line and XII-XII line of FIG. 10A, FIG. 11A and FIG. 12A. First, as shown in FIG. 10A and FIG. 10B, base material 26 having main surface 26a is prepared. Next, through holes 26c and 26d penetrating base material 26 are formed in base material 26. First resistor 21 and second resistor 22, which are thin film resistors, are formed on main surface 26a by sputtering after masking, for example.

Next, as shown in FIG. 11A and FIG. 11B, wire bonding pad 27 and pattern wirings 28, 29, 30, and 31 are formed on main surface 26a of base material 26 by, for example, vapor deposition or sputtering of a conductive material after masking. At this time, wire bonding pad 27 and pattern wiring 28 are formed so that a part of each of them rides on first resistor 21, and the other part of pattern wiring 28 and a part of pattern wiring 30 are formed so that they ride on second resistor 22. Thereafter, plating is performed to thicken wire bonding pad 27 and pattern wirings 28, 29, 30, and 31. Vias 32 and 33 are formed by filling each of through holes 26c and 26d with a conductive material (or depositing a film of a conductive material on the side surface of each of through holes 26c and 26d). A solder resist is formed on main surface 26a so as to surround the region where first capacitor 23 and second capacitor 24 are bonded.

Next, as shown in FIG. 12A and FIG. 12B, first capacitor 23 and second capacitor 24 are disposed on main surface 26a. Then, first electrode 23a of first capacitor 23 is bonded to pattern wiring 28 by conductive bonding material 41, and second electrode 23b of first capacitor 23 is bonded to pattern wiring 29 by conductive bonding material 42. Further, first electrode 24a of second capacitor 24 is bonded to pattern wiring 30 by conductive bonding material 43, and second electrode 24b of second capacitor 24 is bonded to pattern wiring 31 by conductive bonding material 44. Through the above processes, baseband termination circuit 20 of the present embodiment is manufactured.

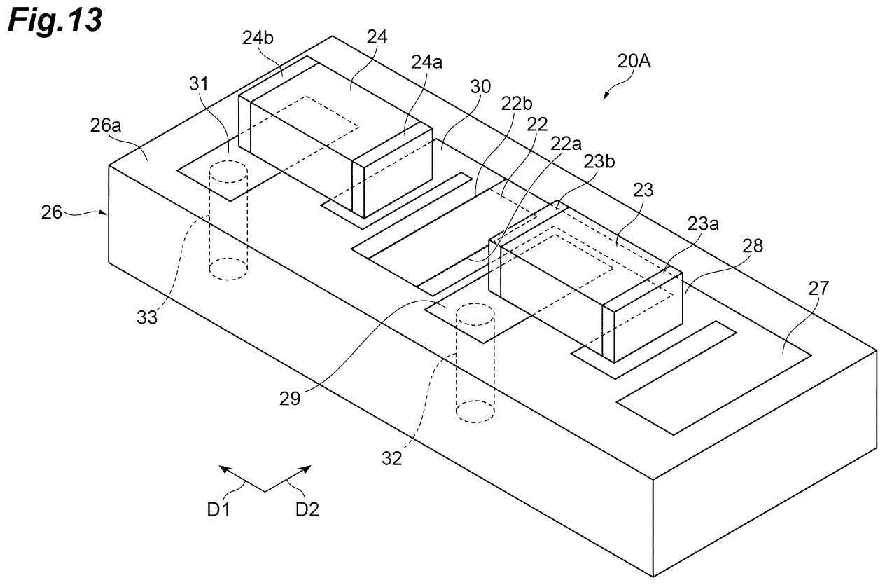

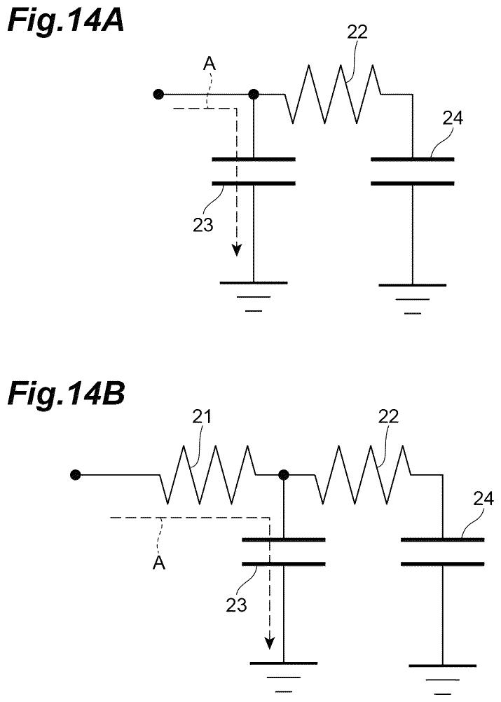

The effect obtained by amplifying circuit 1 of the present embodiment described above will be described with reference to a comparative example. FIG. 13 is a plan view of a baseband termination circuit 20A according to the comparative example. Baseband termination circuit 20A is different from baseband termination circuit 20 in the presence or absence of first resistor 21 and the resistance value of second resistor 22. Baseband termination circuit 20A does not include first resistor 21, and wire bonding pad 27 is formed integrally with pattern wiring 28. The resistance value of second resistor 22 in the comparative example has a value obtained by adding the resistance value of first resistor 21 to the resistance value of second resistor 22 of the present embodiment. FIG. 14A is a circuit diagram of baseband termination circuit 20A according to the comparative example. FIG. 14B is a circuit diagram of baseband termination circuit 20 according to the present embodiment.

In baseband termination circuit 20A according to the comparative example, second resistor 22 having a large resistance value generates heat, and the temperature at or near second resistor 22 locally rises. An excessive temperature rises at or near second resistor 22 affects the operation and life of second resistor 22.

In contrast, in baseband termination circuit 20 of the present embodiment, first resistor 21 is provided in addition to second resistor 22. In this case, the resistance value of second resistor 22 can be made lower than the resistance value of second resistor 22 in the comparative example by the resistance value of first resistor 21. That is, it is possible to disperse the heat generation points compared to the case where there is only one resistor. Thus, according to baseband termination circuit 20 of the present embodiment, heat dissipation for the heat generated in the resistor can be improved.

Further, according to baseband termination circuit 20 of the present embodiment, first resistor 21 is provided, and thus it is possible to increase the attenuation rate of the frequency component (arrow A in the drawing) passing through first capacitor 23. When the capacitance value of first capacitor 23 is smaller than the capacitance value of second capacitor 24, the high frequency component passes through first capacitor 23. In this case, the attenuation rate in the high frequency band can be increased by providing first resistor 21.

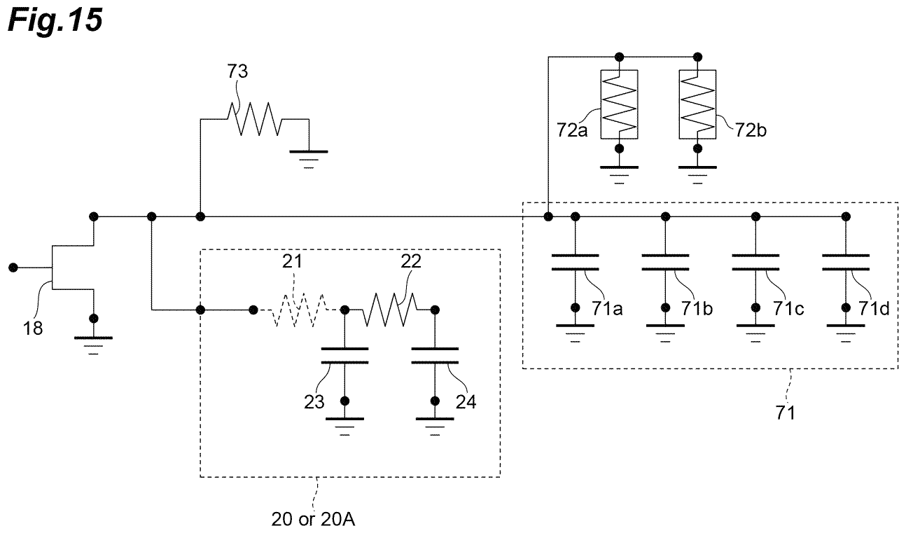

FIG. 15 is a diagram showing a circuit used in a simulation to confirm the effect of electrical characteristics of a baseband termination circuit. This circuit includes transistor 18, baseband termination circuit 20 (or baseband termination circuit 20A), a capacitor portion 71, voltage sensing resistors 72a and 72b, and a fundamental frequency matching load 73. A first current terminal of transistor 18 is connected to a reference potential via fundamental frequency matching load 73. Capacitor portion 71 includes four capacitors 71a, 71b, 71c, and 71d connected in parallel to each other between the first current terminal of transistor 18 and the reference potential. Capacitance values of capacitors 71a, 71b, 71c, and 71d are different from each other. In this simulation, the capacitance values of capacitors 71a, 71b, 71c, and 71d are set to 1000 pF, 8.2 nF, 0.2 nF, and 4.7 nF, respectively. Further, the resistance values of first resistor 21 and second resistor 22 of baseband termination circuit 20 are set to 1 Ω and 2 Ω, respectively, and the resistance value of second resistor 22 of baseband termination circuit 20A is set to 3 Ω. Furthermore, the capacitance values of first capacitor 23 and second capacitor 24 are set to 130 pF and 1500 pF, respectively.

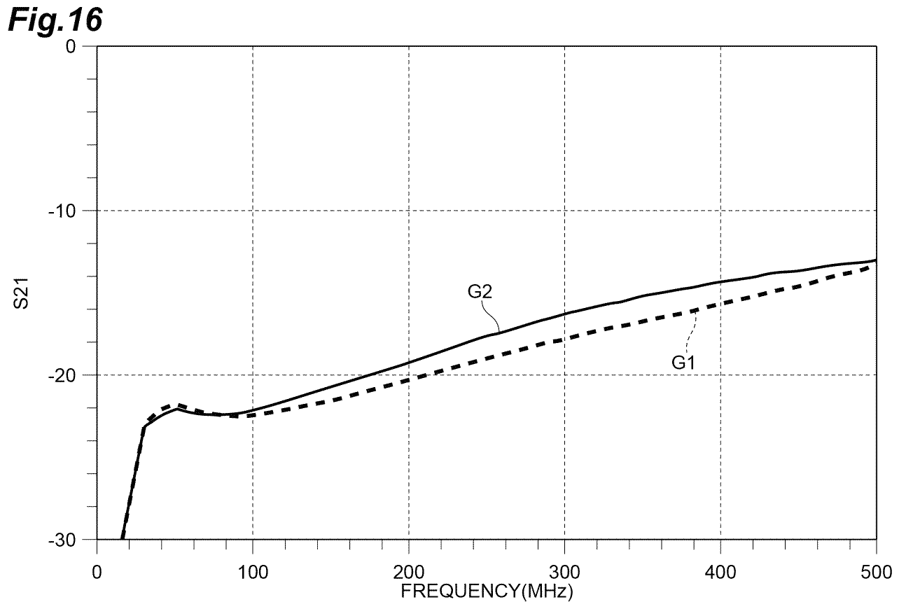

FIG. 16 is a graph showing simulation results. In FIG. 16, the horizontal axis represents a frequency (MHz), and the vertical axis represents a characteristic value S21 when voltage sensing resistor 72a is set to a port 1 and voltage sensing resistor 72b is set to a port 2. In the figure, a line G1 indicates a simulation result of baseband termination circuit 20 of the present embodiment, and a line G2 indicates a simulation result of baseband termination circuit 20A of the comparative example. As shown in the figure, in a high frequency band of 100 MHz or more, characteristic value S21 of the present embodiment is smaller than characteristic value S21 of the comparative example. From this, it can be said that baseband termination circuit 20 of the present embodiment has a larger attenuation effect in the high frequency band compared to baseband termination circuit 20A of the comparative example.

As in the present embodiment, the resistance value of first resistor 21 may be smaller than the resistance value of second resistor 22. The high frequency component and the low frequency component flow through first resistor 21, and only the low frequency component flows through second resistor 22. Thus, the amount of current flowing through first resistor 21 is larger than the amount of current flowing through second resistor 22. On the other hand, from the viewpoint of heat dispersion, it is desirable that the amount of heat generation (that is, power consumption) in first resistor 21 and the amount of heat generation (that is, power consumption) in second resistor 22 are uniform or nearly uniform. Since the resistance value of first resistor 21 is smaller than the resistance value of second resistor 22, the amount of heat generated in first resistor 21 and the amount of heat generated in second resistor 22, which has a smaller current than first resistor 21, can be made close to be uniform.

As in the present embodiment, amplifying circuit 1 may include base material 26 having main surface 26a on which first resistor 21, second resistor 22, first capacitor 23, and second capacitor 24 are provided. On main surface 26a, first capacitor 23, second capacitor 24, or both first capacitor 23 and second capacitor 24 may be disposed between first resistor 21 and second resistor 22. In this case, since first resistor 21 and second resistor 22 can be sufficiently spaced apart from each other, heat generation points can be effectively dispersed, and heat dissipation can be further improved.

As in the present embodiment, main surface 26a may have a rectangular planar shape elongated in direction D1. First resistor 21 and second resistor 22 may have a rectangular planar shape elongated in direction D2 intersecting direction D1. In this case, it is possible to improve heat dissipation while avoiding base material 26 from becoming long in direction D1 and maintaining a sufficient distance between first resistor 21 and second resistor 22.

As in the present embodiment, amplifying circuit 1 may include wire bonding pad 27 provided on main surface 26a and connected to first end 21a of first resistor 21, and a bonding wire (wire 25) connecting wire bonding pad 27 to a wiring between amplifier 11 and output terminal 1b. First resistor 21 may be disposed between wire bonding pad 27 and first capacitor 23. In this case, wire bonding pad 27 and first resistor 21 can be efficiently disposed on main surface 26a.

As in the present embodiment, first resistor 21 and second resistor 22 may be film resistors formed on main surface 26a. Thus, first resistor 21 and second resistor 22 are in close contact with base material 26, and thus heat dissipation can be improved as compared to the case where a surface-mounted chip resistor is used.

### Modification

In the above-described embodiment, the case where first resistor 21 and second resistor 22 are thin film resistors is exemplified. However, the first resistor and the second resistor may be diffused resistors formed by diffusing an impurity in a region including a part of main surface 26a in base material 26 (that is, from main surface 26a of base material 26 to the inside of base material 26). In this case, base material 26 is a semiconductor substrate such as a Si substrate. The impurity is an n-type impurity such as boron when base material 26 is a p-type Si substrate, and is a p-type impurity such as phosphorus or arsenic when base material 26 is an n-type Si substrate. Base material 26 is a Si substrate, and thus the diffused resistor can be easily formed.

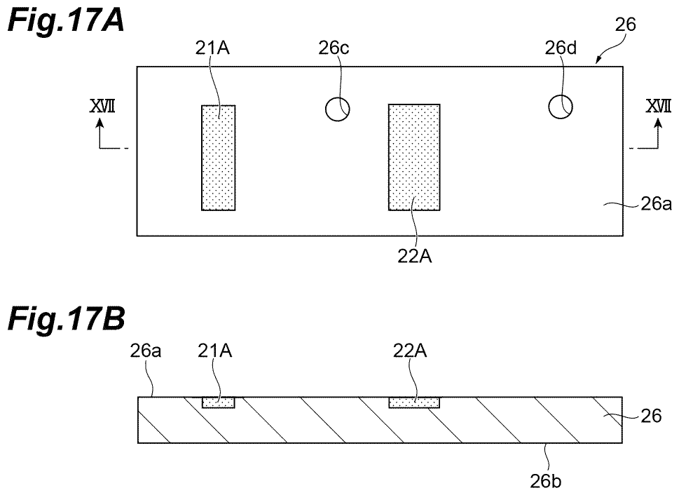

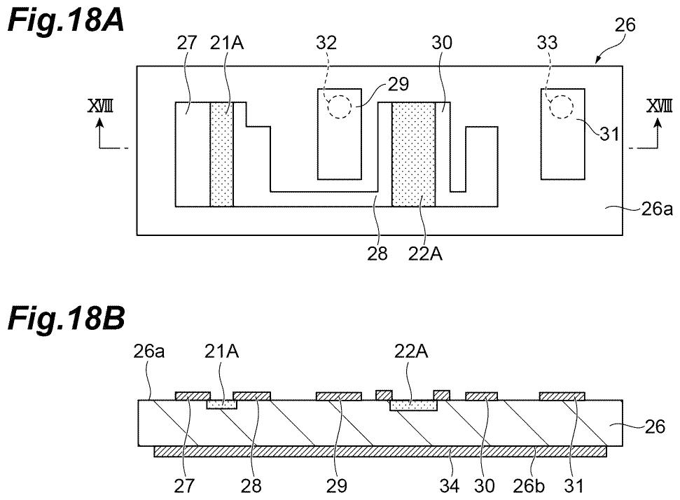

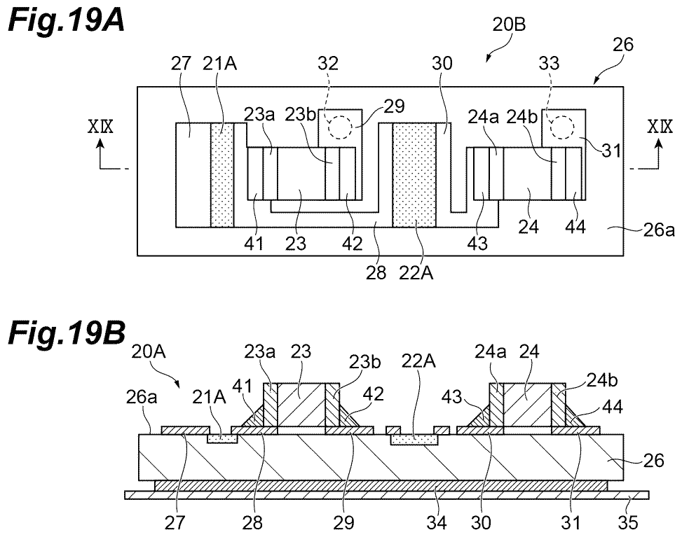

FIG. 17A, FIG. 17B, FIG. 18A, FIG. 18B, FIG. 19A and FIG. 19B are diagrams each showing a manufacturing process of baseband termination circuit 20B, which is the modification. Each of FIG. 17A, FIG. 18A and FIG. 19A shows a plan view, and each of FIG. 17B, FIG. 18B and FIG. 19B shows a cross-sectional view taken along each of XVII-XVII line, XVIII-XVIII line and XIX-XIX line of FIG. 17A, FIG. 18A and FIG. 19A. First, as shown in FIG. 17A and 17B, base material 26 having main surface 26a is prepared. Next, through holes 26c and 26d penetrating base material 26 are formed in base material 26. Next, after masking, an impurity is implanted and diffused from main surface 26a of base material 26 to the inside of base material 26, thereby forming a first resistor 21A and a second resistor 22A, which are diffused resistors, in main surface 26a.

Next, as shown in FIG. 18A and 18B, wire bonding pad 27 and pattern wirings 28, 29, 30, and 31 are formed on main surface 26a of base material 26 by, for example, vapor deposition or sputtering of a conductive material after masking. At this time, a part of each of wire bonding pad 27 and pattern wiring 28 is formed on first resistor 21A, and the other part of pattern wiring 28 and a part of pattern wiring 30 are formed on second resistor 22A. Thereafter, plating is performed to thicken wire bonding pad 27 and pattern wirings 28, 29, 30, and 31. Vias 32 and 33 are formed by filling each of through holes 26c and 26d with a conductive material (or depositing a film of a conductive material on the side surfaces of each of through holes 26c and 26d). A solder resist is formed on main surface 26a so as to surround the region where first capacitor 23 and second capacitor 24 are bonded.

Next, as shown in FIG. 19A and 19B, first capacitor 23 and second capacitor 24 are disposed on main surface 26a. Then, first electrode 23a of first capacitor 23 is bonded to pattern wiring 28 by conductive bonding material 41, and second electrode 23b of first capacitor 23 is bonded to pattern wiring 29 by conductive bonding material 42. Further, first electrode 24a of second capacitor 24 is bonded to pattern wiring 30 by conductive bonding material 43, and second electrode 24b of second capacitor 24 is bonded to pattern wiring 31 by conductive bonding material 44. Through the above processes, baseband termination circuit 20B of the present embodiment is manufactured.

As in this modification, first resistor 21A and second resistor 22A may be diffused resistors formed in a region including a part of main surface 26a in base material 26. Thus, first resistor 21A and second resistor 22A are included in base material 26, and thus, heat dissipation can be improved as compared to the case where a surface-mounted chip resistor is used.

The amplifying circuit according to the present disclosure is not limited to the above-described embodiments, and various modifications can be made. For example, in the above embodiment, internal output matching circuit 12 is provided on the output side of amplifier 11, and internal input matching circuit 13 is provided on the input side of amplifier 11, but only one of internal output matching circuit 12 and internal input matching circuit 13 may be provided. Further, in the above embodiment, the case where first capacitor 23 and second capacitor 24 are multilayer microchip capacitors is exemplified. However, first capacitor 23 and second capacitor 24 may have other forms. Furthermore, in the above embodiment, the case where first resistor 21 and second resistor 22 are resistance films is exemplified. However, first resistor 21 and second resistor 22 may have other forms.

What is claimed is:

1. An amplifying circuit comprising:
an amplifier configured to amplify a high frequency signal and output the high frequency signal that is amplified to an output terminal;
a first resistor having a first end and a second end, the first end being connected to a wiring between the amplifier and the output terminal;
a second resistor having a first end and a second end, the first end being connected to the second end of the first resistor;
a first capacitor having a first electrode and a second electrode, the first electrode being connected to a node between the second end of the first resistor and the first end of the second resistor, the second electrode being connected to a reference potential; and
a second capacitor having a first electrode and a second electrode, the first electrode being connected to the second end of the second resistor, the second electrode being connected to the reference potential.

2. The amplifying circuit according to claim 1,
wherein a resistance value of the first resistor is smaller than a resistance value of the second resistor.

3. The amplifying circuit according to claim 1, further comprising:
a base material having a main surface on which the first resistor, the second resistor, the first capacitor, and the second capacitor are provided, wherein, on the main surface, the first capacitor, the second capacitor, or both the first capacitor and the second capacitor are disposed between the first resistor and the second resistor.

4. The amplifying circuit according to claim 3,
wherein the main surface has a rectangular planar shape elongated in a first direction, and
wherein the first resistor and the second resistor have a rectangular planar shape elongated in a second direction intersecting the first direction.

5. The amplifying circuit according to claim 3, further comprising:
a wire bonding pad provided on the main surface and connected to the first end of the first resistor; and
a bonding wire connecting the wire bonding pad to the wiring,
wherein the first resistor is disposed between the wire bonding pad and the first capacitor.

6. The amplifying circuit according to claim 1, further comprising:
a base material having a main surface on which the first resistor, the second resistor, the first capacitor, and the second capacitor are provided,
wherein the first resistor and the second resistor are film resistors formed on the main surface.

7. The amplifying circuit according to claim 1, further comprising:
a base material having a main surface on which the first resistor, the second resistor, the first capacitor, and the second capacitor are provided,
wherein the first resistor and the second resistor are diffused resistors formed in the base material.
